(19) United States
(12) Patent Application Publication
(10) Pub. No.: US 2024/0324242 A1
(43) Pub. Date: Sep. 26, 2024

(54) MEMORY DEVICE

(71) Applicant: Kioxia Corporation, Tokyo (JP)

(72) Inventors: Kazuya SAWADA, Seoul (KR); Toshihiko NAGASE, Seoul (KR); Kenichi YOSHINO, Seongnam-si Gyeonggi-do (KR); Hyungjun CHO, Seoul (KR); Naoki AKIYAMA, Seoul (KR); Takuya SHIMANO, Seoul (KR)

(73) Assignee: Kioxia Corporation, Tokyo (JP)

(21) Appl. No.: 18/605,999

(22) Filed: Mar. 15, 2024

(30) Foreign Application Priority Data
Mar. 20, 2023 (JP) 2023-044602

(51) Int. Cl. H10B 61/00; H10N 50/10; H10N 50/80

(52) U.S. Cl. CPC H10B 61/10; H10N 50/10; H10N 50/80

(57) ABSTRACT

According to one embodiment, a memory device includes a first wiring line extending along a first direction, a second wiring line provided on an upper layer side of the first wiring line and extending along a second direction intersecting the first direction, and a memory cell provided between the first wiring line and the second wiring line, and including a magnetoresistance effect element, a switching element, a middle electrode provided between the magnetoresistance effect element and the switching element, and a resistive layer provided between the magnetoresistance effect element and the second wiring line. A resistance of the resistive layer is higher than a resistance of the middle electrode.

### CROSS-REFERENCE TO RELATED APPLICATIONS

This application is based upon and claims the benefit of priority from Japanese Patent Application No. 2023-044602, filed Mar. 20, 2023, the entire contents of which are incorporated herein by reference.

### FIELD

Embodiments described herein relate generally to a memory device.

### BACKGROUND

A memory device has been proposed in which memory cells including magnetoresistance effect elements and selectors (switching elements) are integrated on a semiconductor substrate.

### BRIEF DESCRIPTION OF THE DRAWINGS

FIG. 1 is a perspective diagram schematically showing a basic configuration of a memory device according to a first embodiment.

FIG. 2 is a cross-sectional view schematically showing a detailed configuration of a memory cell in the memory device of the first embodiment.

FIG. 3 is a diagram schematically showing the current-voltage characteristics of a selector in the memory device of the first embodiment.

FIG. 4 is a cross-sectional view schematically showing a detailed configuration of a memory cell in a first modified example of the memory device according to the first embodiment.

FIG. 5 is a cross-sectional view schematically showing a detailed configuration of a memory cell in a second modified example of the memory device according to the first embodiment.

FIG. 6 is a cross-sectional view schematically showing a detailed configuration of a memory cell in a third modified example of the memory device according to the first embodiment.

FIG. 7 is a perspective diagram schematically showing a basic configuration of a memory device according to a second embodiment.

FIG. 8 is a cross-sectional view schematically showing a detailed configuration of a memory cell in the memory device of the second embodiment.

FIG. 9 is a cross-sectional view schematically showing a detailed configuration of a memory cell in a first modified example of the memory device according to the second embodiment.

FIG. 10 is a cross-sectional view schematically showing a detailed configuration of a memory cell in a second modified example of the memory device according to the second embodiment.

FIG. 11 is a cross-sectional view schematically showing a detailed configuration of a memory cell in a third modified example of the memory device according to the second embodiment.

FIG. 12 is a cross-sectional view schematically showing a detailed configuration of a memory cell in a fourth modified example of the memory device according to the second embodiment.

FIG. 13 is a cross-sectional view schematically showing a detailed configuration of a memory cell in a fifth modified example of the memory device according to the second embodiment.

FIG. 14 is a cross-sectional view schematically showing a detailed configuration of a memory cell in a sixth modified example of the memory device according to the second embodiment.

FIG. 15 is a cross-sectional view schematically showing a detailed configuration of a memory cell in a seventh modified example of the memory device according to the second embodiment.

### DETAILED DESCRIPTION

In general, according to one embodiment, a memory device includes: a first wiring line extending along a first direction; a second wiring line provided on an upper layer side of the first wiring line and extending along a second direction intersecting the first direction; and a memory cell provided between the first wiring line and the second wiring line, and including a magnetoresistance effect element, a switching element, a middle electrode provided between the magnetoresistance effect element and the switching element, and a resistive layer provided between the magnetoresistance effect element and the second wiring line, wherein a resistance of the resistive layer is higher than a resistance of the middle electrode.

Embodiments will be described hereinafter with reference to the accompanying drawings.

### First Embodiment

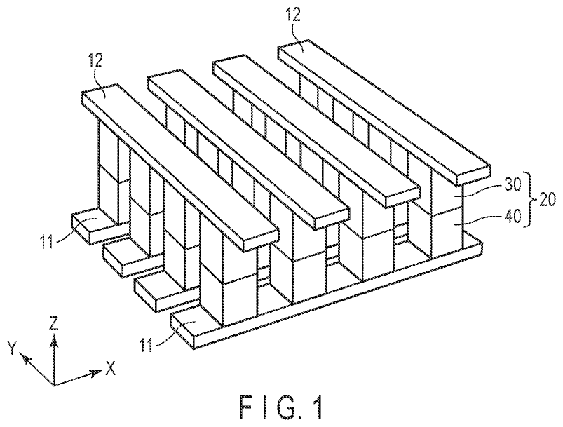

FIG. 1 is a perspective view schematically showing a basic configuration of a memory device according to the first embodiment.

Note that X, Y, and Z directions shown in FIG. 1 are directions that intersect each other. More specifically, the X, Y, and Z directions are orthogonal to each other. This is also the case for the other figures.

The memory device shown in FIG. 1 includes wiring lines 11 extending along the X direction, wiring lines 12 provided on an upper layer side of the wiring lines 11 and extending along the Y direction, and memory cells 20 each provided between each respective one of the wiring lines 11 and each respective one of the wiring lines 12.

The memory cells 20 each include a magnetoresistance effect element 30 and a selector (switching element) 40 connected in series to the magnetoresistance effect element 30. The magnetoresistance effect element 30 and the selector 40 are stacked one on another along the Z direction. In this embodiment, the magnetoresistance effect element 30 is provided on an upper layer side of the selector 40.

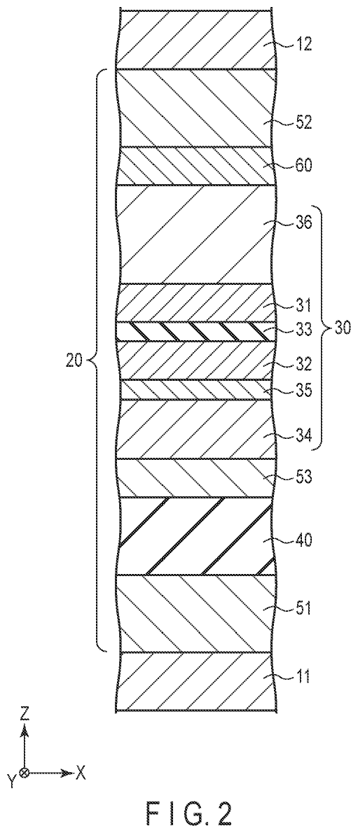

FIG. 2 is a cross-sectional view schematically showing a detailed configuration of the memory cell 20.

As already described, each memory cell 20 is provided between a wiring line 11 extending along the X direction and a wiring line 12 extending along the Y direction, and includes the magnetoresistance effect element 30, the selector 40, a bottom electrode 51, a top electrode 52, a middle electrode 53 provided between the magnetoresistance effect element 30 and the selector 40, and a resistive layer 60 provided between the magnetoresistance effect element 30 and the wiring line 12. These elements are stacked one on another between the wiring line 11 and the wiring line 12.

The magnetoresistance effect element 30 is a magnetic tunnel junction (MTJ) element, and includes a storage layer (first magnetic layer) 31, a reference layer (second magnetic layer) 32, a tunnel barrier layer (nonmagnetic layer) 33, a superlattice layer (third magnetic layer) 34, an intermediate layer 35, and an auxiliary layer 36. These layers are stacked one on another between the top electrode 52 and the middle electrode 53. That is, the top electrode 52 functions as a top electrode to the magnetoresistance effect element 30, and the middle electrode 53 functions as a bottom electrode to the magnetoresistance effect element 30. Note that the top electrode 52 functions as a cap layer as well. The middle electrode 53 is formed of titanium nitride (TiN) containing titanium (Ti) and nitrogen (N). The middle electrode 53 may as well be formed of tungsten nitride (WN) containing tungsten (W) and nitrogen (N), tantalum nitride (TaN) containing tantalum (Ta) and nitrogen (N), or the like.

The magnetoresistance effect element 30 is a top-free type magnetoresistance effect element in which the storage layer 31 is located on an upper layer side of the reference layer 32.

The storage layer 31 is a ferromagnetic layer having a variable magnetization direction and is formed, for example, from a CoFeB layer containing cobalt (Co), iron (Fe), and boron (B). The variable magnetization direction means that the magnetization direction changes for a predetermined write current.

The reference layer 32 is a ferromagnetic layer having a fixed magnetization direction and is formed, for example, from a CoFeB layer containing cobalt (Co), iron (Fe), and boron (B). The fixed magnetization direction means that the magnetization direction does not change for a predetermined write current.

The tunnel barrier layer 33 is an insulating layer provided between the storage layer 31 and the reference layer 32, and is formed, for example, from an MgO layer containing magnesium (Mg) and oxygen (O).

The superlattice layer 34 is a layer formed, for example, from a superlattice of cobalt (Co) and platinum (Pt). The reference layer 32 described above is provided between the tunnel barrier layer 33 and the superlattice layer 34, and the reference layer 32 and the superlattice layer 34 are antiferromagnetically coupled (antiferromagnetic coupling) to each other through the intermediate layer 35 provided between the reference layer 32 and the superlattice layer 34. In other words, the reference layer 32, the superlattice layer 34, and the intermediate layer 35 form a synthetic antiferromagnetic (SAF) structure.

The auxiliary layer 36 is a layer for enhancing the perpendicular magnetic anisotropy of the storage layer 31, and the storage layer 31 is provided between the tunnel barrier layer 33 and the auxiliary layer 36.

The magnetoresistance effect element 30 described above exhibits a low resistance state when the magnetization direction of the storage layer 31 is parallel to that of the reference layer 32, and a high resistance state when the magnetization direction of the storage layer 31 is antiparallel to that of the reference layer 32. With this configuration, the magnetoresistance effect element 30 can store binary data according to its resistance state. Further, the magnetoresistance effect element 30 is a spin transfer torque (STT) type magnetoresistance effect element having perpendicular magnetization, and the magnetization direction of the storage layer 31 is perpendicular to its main surface and the magnetization direction of the reference layer 32 is perpendicular to its main surface.

The selector 40 is a two-terminal type switching element and includes a selector material layer. The selector material layer contains an insulating material and an additive element. For example, an oxide such as silicon oxide is used for the insulating material, and arsenic (As) or the like is used as the additive element. The selector material layer is provided between the bottom electrode 51 and the middle electrode 53. In other words, the bottom electrode 51 functions as a bottom electrode for the selector 40, and the middle electrode 53 functions as a top electrode for the selector 40.

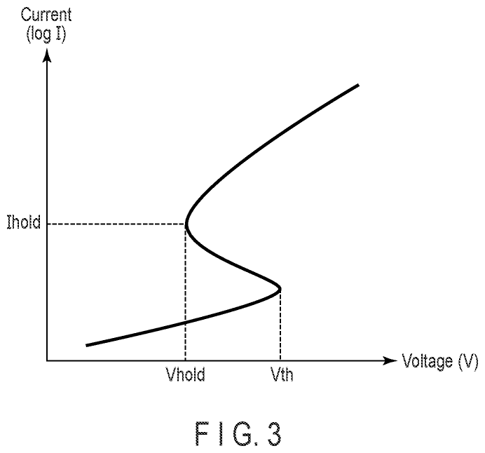

FIG. 3 is a diagram schematically showing current-voltage characteristics of the selector 40. As shown in FIG. 3, the selector 40 has such characteristics that it changes from an off state to an on state when the voltage applied between the two terminals (between the bottom electrode 51 and the middle electrode 53) is higher than a threshold voltage Vth. Further, the selector 40 has characteristics of changing from the on state to the off state when the voltage applied between the two terminals becomes lower than a hold voltage Vhold. Here, the current Ihold is the current flowing in the selector 40 when the voltage applied between the two terminals is the hold voltage Vhold and the on state is maintained.

The resistive layer 60 is provided on the upper layer side of the magnetoresistance effect element 30 and on the lower layer side of the wiring line 12. In the example of FIG. 2, the resistive layer 60 is provided on the lower layer side of the top electrode 52.

The resistance of the resistive layer 60 is higher than that of the middle electrode 53. More specifically, the resistance of the resistive layer 60 in the Z direction is higher than that of the middle electrode 53 in the Z direction. In other words, the resistivity of the material of the resistive layer 60 is higher than the resistivity of the material of the middle electrode 53.

The resistive layer 60 is formed of a semiconductor material. In this embodiment, the middle electrode 53 is formed of titanium nitride (TiN). Therefore, the resistive layer 60 is formed of a material having a resistivity higher than that of titanium nitride (TiN). For example, the resistive layer 60 is formed of a semiconductor material such as of silicon (Si), germanium (Ge), carbon (C) or the like. These semiconductor materials (Si, Ge, and C) each may contain an n-type or p-type impurity.

As described above, in the memory device of this embodiment, the resistive layer 60 is provided on the upper layer side of the magnetoresistance effect element 30. With this configuration, it is possible to obtain a memory device including the memory cells 20 with excellent characteristics and reliability, as will be described later.

In the memory device described above, when an ON voltage is applied between the wiring line 11 and the wiring line 12, the selector 40 is turned ON and a write current flows to the magnetoresistance effect element 30 connected in series to the selector 40. As a result, it is possible to set the magnetoresistance effect element 30 to a low-resistance state or a high-resistance state. In other words, data can be written to the memory cell 20.

When writing data to a memory cell 20, the write current becomes higher when the resistance of the memory cell 20 as a whole is low. Normally, when writing data to a memory cell 20, the write current is set so that the current flowing to the selector is higher than the current Ihold shown in FIG. 3. Therefore, when the resistance of the memory cell 20 as a whole is low, the value of the write current Ihold becomes high.

In this embodiment, the resistive layer 60 having a relatively high resistance is connected in series to the magnetoresistance effect element 30 and the selector 40. With this configuration, the resistive layer 60 can suppress the current flowing in the memory cell 20. Therefore, in this embodiment, the write current to the memory cell 20 can be reduced.

Further, to form the pattern of the magnetoresistance effect element 30, ion beam etching (IBE) is usually used. In this case, when the resistive layer 60 is provided on the lower layer side of the magnetoresistance effect element 30, the resistive layer 60 is etched after etching of the magnetoresistance effect element layer. Therefore, the material of the resistive layer 60 may adhere to a side surface of the magnetoresistance effect element 30, which may deteriorate the characteristics of the magnetoresistance effect element 30.

In this embodiment, the resistive layer 60 is provided on the upper layer side of the magnetoresistance effect element 30, etching of the magnetoresistance effect element layer is performed after etching of the resistive layer 60. Therefore, it is possible to prevent the material of the resistive layer 60 from adhering to the side surface of the magnetoresistance effect element 30 and to suppress the deterioration of the characteristics of the magnetoresistance effect element 30.

Further, with the resistive layer 60 thus by provided on the upper layer side of the magnetoresistance effect element 30, it is possible to reduce the variation of the voltage Vhold corresponding to the current Ihold.

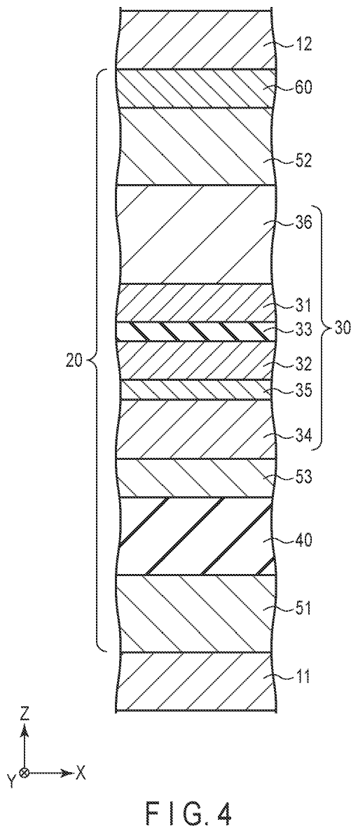

Next, the first modified example of this embodiment will be described. FIG. 4 is a cross-sectional view schematically showing a detailed configuration of a memory cell 20 in this modified example.

In this modified example as well, the resistive layer 60 is provided on the upper layer side of the magnetoresistance effect element 30 and on the lower layer side of the wiring line 12, and the magnetoresistance effect element 30 is provided on the upper layer side of the selector 40 as in the case of the embodiment described above. Further, in this modified example, the magnetoresistance effect element 30 is a top-free type magnetoresistance effect element in which the storage layer 31 is located on the upper layer side of the reference layer 32. But note that in this modified example, the resistive layer 60 is provided on the upper layer side of the top electrode 52.

In this modified example as well, the resistance of the resistive layer 60 is higher than that of the middle electrode 53, and the resistive layer 60 is provided on the upper layer side of the magnetoresistance effect element 30. Therefore, in this modified example, advantageous effects similar to those of the embodiment described above can be obtained.

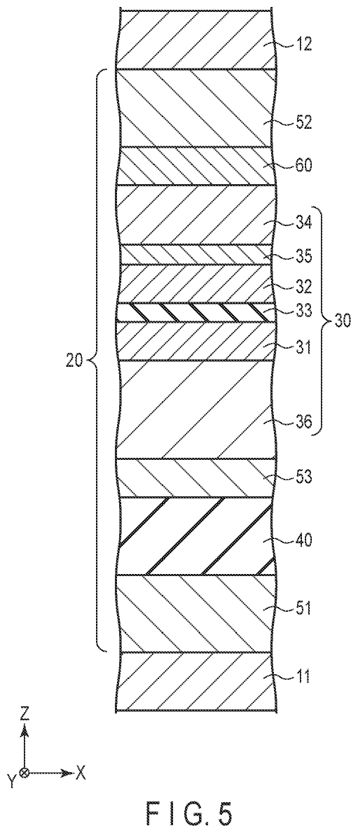

Next, the second modified example of this embodiment will be described. FIG. 5 is a cross-sectional view schematically showing a detailed configuration of the memory cell 20 in this modified example.

In this modified example as well, the resistive layer 60 is provided on the upper layer side of the magnetoresistance effect element 30 and on the lower layer side of the wiring line 12, and the magnetoresistance effect element 30 is provided on the upper layer side of the selector 40 as in the embodiment described above. But note that in this modified example, the magnetoresistance effect element 30 is a bottom-free type magnetoresistance effect element in which the storage layer 31 is located on the lower layer side of the reference layer 32. Further, in this modified example, the resistive layer 60 is provided on the lower layer side of the top electrode 52.

In this modified example as well, the resistance of the resistive layer 60 is higher than that of the middle electrode 53, and the resistive layer 60 is provided on the upper layer side of the magnetoresistance effect element 30. Therefore, in this modified example, advantageous effects similar to those of the embodiment described above can be obtained.

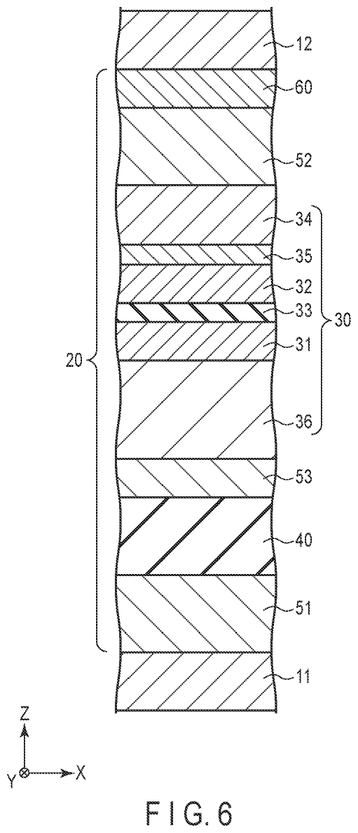

Next, the third modified example of this embodiment will be described. FIG. 6 is a cross-sectional view schematically showing a detailed configuration of the memory cell 20 in this modified example.

In this modified example as well, the resistive layer 60 is provided on the upper layer side of the magnetoresistance effect element 30 and on the lower layer side of the wiring line 12, and the magnetoresistance effect element 30 is provided on the upper layer side of the selector 40 as in the embodiment described above. But note that in this modified example, the magnetoresistance effect element 30 is a bottom-free type magnetoresistance effect element in which the storage layer 31 is located on the lower layer side of the reference layer 32. Further, in this modified example, the resistive layer 60 is provided on the upper layer side of the top electrode 52.

In this modified example as well, the resistance of the resistive layer 60 is higher than that of the middle electrode 53, and the resistive layer 60 is provided on the upper layer side of the magnetoresistance effect element 30. Therefore, in this modified example, advantageous effects similar to those of the embodiment described above can be obtained.

### Second Embodiment

Next, the second embodiment will be described. Note that the basic items are similar to those of the first embodiment, and the explanations of the items already described in the first embodiment will be omitted.

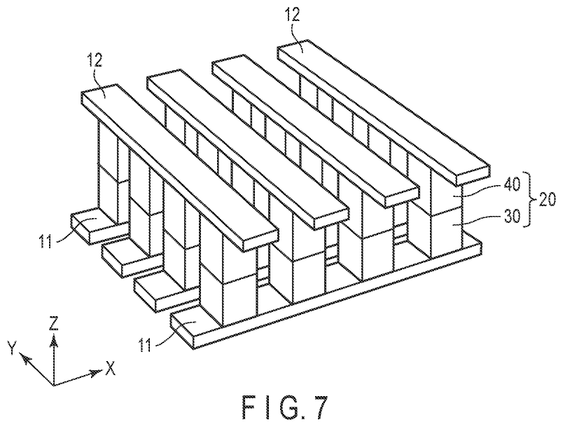

FIG. 7 is a perspective view schematically showing a basic configuration of a memory device according to the second embodiment.

In this embodiment as well, each memory cell 20 includes a magnetoresistance effect element 30 and a selector 40 connected in series with each other, and the magnetoresistance effect element 30 and the selector 40 are stacked one on another along the Z direction as in the first embodiment. However, in this embodiment, the magnetoresistance effect element 30 is provided on the lower layer side of selector 40.

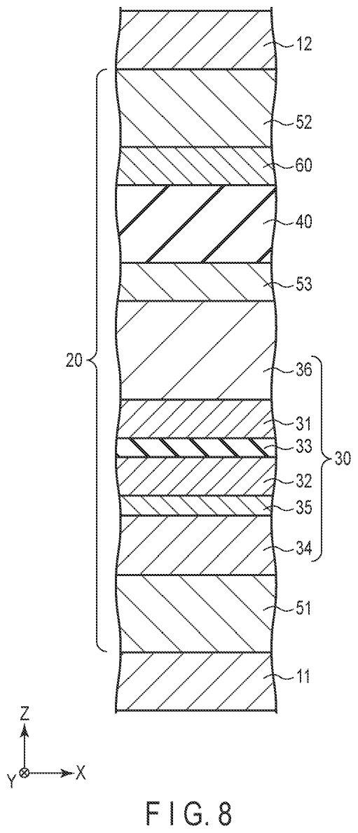

FIG. 8 is a cross-sectional view schematically showing a detailed configuration of the memory cell 20.

In this embodiment as well, the memory cell 20 is provided between a wiring line 11 extending along the X direction and a wiring line 12 extending along the Y direction, and includes the magnetoresistance effect element 30, the selector 40, a bottom electrode 51, a top electrode 52, a middle electrode 53 provided between the magnetoresistance effect element 30 and the selector 40, and a resistive layer 60 provided between the magnetoresistance effect element 30 and the wiring line 12. These elements are stacked one on another between the wiring line 11 and the wiring line 12, and the basic configuration of each element is similar to that of the first embodiment.

Further, in this embodiment as well, the resistive layer 60 is provided between the magnetoresistance effect element 30 and the wiring line 12, that is, on the upper layer side of the magnetoresistance effect element 30 and the lower layer side of the wiring line 12 as in the case of the first embodiment. In the example of FIG. 8, the resistive layer 60 is provided on the upper layer side of the selector 40. Further, in the example of FIG. 8, the resistive layer 60 is provided on the lower layer side of the top electrode 52. Furthermore, in the example of FIG. 8, the magnetoresistance effect element 30 is a top-free type magnetoresistance effect element in which the storage layer 31 is located on the upper layer side of the reference layer 32.

Moreover, in this embodiment, the resistance of the resistive layer 60 is higher than that of the middle electrode 53 as in the case of the first embodiment. More specifically, the resistance of the resistive layer 60 in the Z direction is higher than that of the middle electrode 53 in the Z direction. In other words, the resistivity of the material of the resistive layer 60 is higher than the resistivity of the material of the middle electrode 53. The material of the resistive layer 60 and the material of the middle electrode 53 are similar to those of the first embodiment.

As described above, in this embodiment, the magnetoresistance effect element 30 is provided on the lower layer side of the selector 40. With this configuration, the bottom electrode 51 functions as a bottom electrode to the magnetoresistance effect element 30, and the middle electrode 53 functions as a top electrode to the magnetoresistance effect element 30. Further, the top electrode 52 functions as a top electrode to the selector 40, and the middle electrode 53 functions as a bottom electrode to the selector 40.

In this embodiment as well, the resistance of the resistive layer 60 is higher than that of the middle electrode 53, and the resistive layer 60 is provided on the upper layer side of the magnetoresistance effect element 30 as in the case of the first embodiment. Therefore, in this embodiment as well, advantageous effects similar to those of the first embodiment described above can be obtained.

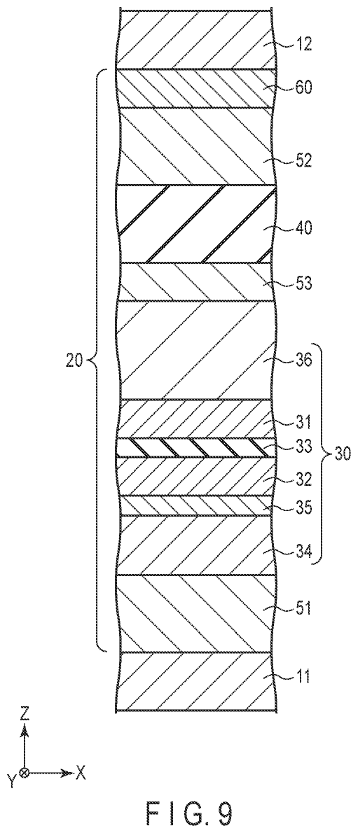

Next, the first modified example of this embodiment will be described. FIG. 9 is a cross-sectional view schematically showing a detailed configuration of the memory cells 20 in this modified example.

In this modified example as well, the resistive layer 60 is provided on the upper layer side of the magnetoresistance effect element 30 and on the lower layer side of the wiring line 12, and the resistive layer 60 is provided on the upper layer side of the selector 40, as in the case of the embodiment described above. But note that, in this modified example, the resistive layer 60 is provided on the upper layer side of the top electrode 52. Further, the magnetoresistance effect element 30 is a top-free type magnetoresistance effect element in which the storage layer 31 is located on the upper layer side of the reference layer 32.

In this modified example as well, the resistance of the resistive layer 60 is higher than that of the middle electrode 53, and the resistive layer 60 is provided on the upper layer side of the magnetoresistance effect element 30. Therefore, in this embodiment as well, advantageous effects similar to those of the embodiment described above can be obtained.

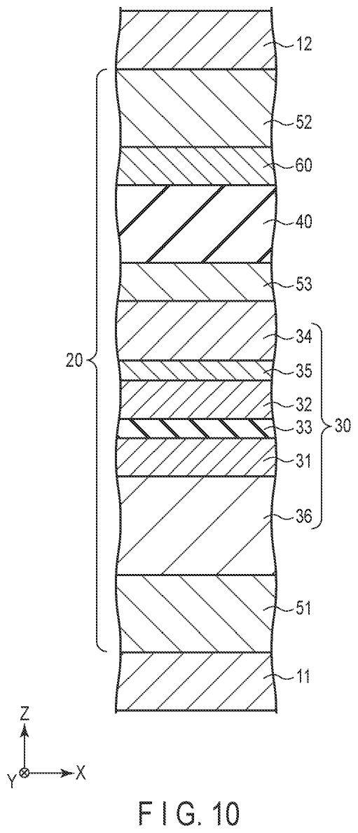

Next, the second modified example of this embodiment will be described. FIG. 10 is a cross-sectional view schematically showing a detailed configuration of the memory cells 20 in this modified example.

In this modified example as well, the resistive layer 60 is provided on the upper layer side of the magnetoresistance effect element 30 and on the lower layer side of the wiring line 12, and the resistive layer 60 is provided on the upper layer side of the selector 40, as in the case of the embodiment described above. Further, in this modified example, the resistive layer 60 is provided on the lower layer side of the top electrode 52. Moreover, the magnetoresistance effect element 30 is a bottom-free type magnetoresistance effect element in which the storage layer 31 is located on the lower layer side of the reference layer 32.

In this modified example as well, the resistance of the resistive layer 60 is higher than that of the middle electrode 53, and the resistive layer 60 is provided on the upper layer side of the magnetoresistance effect element 30. Therefore, in this modified example as well, advantageous effects similar to those of the embodiment described above can be obtained.

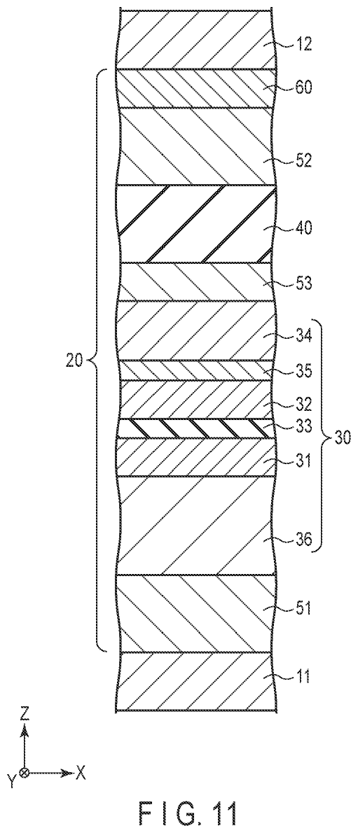

Next, the third modified example of this embodiment will be described. FIG. 11 is a cross-sectional view schematically showing a detailed configuration of the memory cells 20 in this modified example.

In this modified example as well, the resistive layer 60 is provided on the upper layer side of the magnetoresistance effect element 30 and on the lower layer side of the wiring line 12, and the resistive layer 60 is provided on the upper layer side of the selector 40, as in the case of the embodiment described above. Further, in this modified example, the resistive layer 60 is provided on the upper layer side of the top electrode 52. Moreover, the magnetoresistance effect element 30 is a bottom-free type magnetoresistance effect element in which the storage layer 31 is located on the lower layer side of the reference layer 32.

In this modified example as well, the resistance of the resistive layer 60 is higher than that of the middle electrode 53, and the resistive layer 60 is provided on the upper layer side of the magnetoresistance effect element 30. Therefore, in this modified example as well, advantageous effects similar to those of the embodiment described above can be obtained.

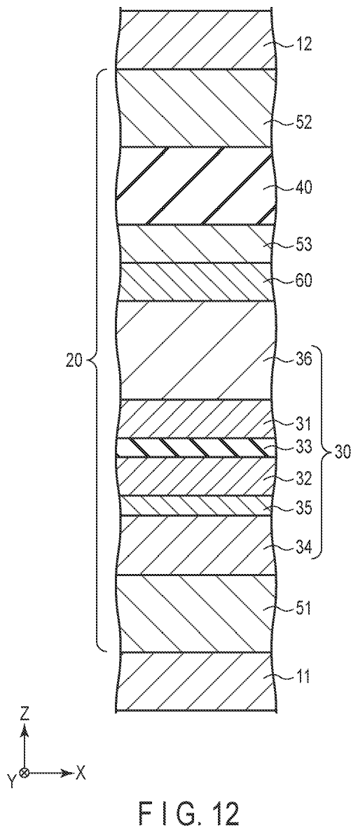

Next, the fourth modified example of this embodiment will be described. FIG. 12 is a cross-sectional view schematically showing a detailed configuration of the memory cells 20 in this modified example.

In this modified example, the resistive layer 60 is provided on the upper layer side of the magnetoresistance effect element 30 and on the lower layer side of the wiring line 12 as in the embodiment described above. But note that, in this modified example, the resistive layer 60 is provided on the lower layer side of the selector 40. Further, in this modified example, the resistive layer 60 is provided on the lower layer side of the middle electrode 53. Moreover, the magnetoresistance effect element 30 is a top-free type magnetoresistance effect element in which the storage layer 31 is located on the upper layer side of the reference layer 32.

In this modified example as well, the resistance of the resistive layer 60 is higher than that of the middle electrode 53, and the resistive layer 60 is provided on the upper layer side of the magnetoresistance effect element 30. Therefore, in this modified example as well, advantageous effects similar to those of the embodiment described above can be obtained.

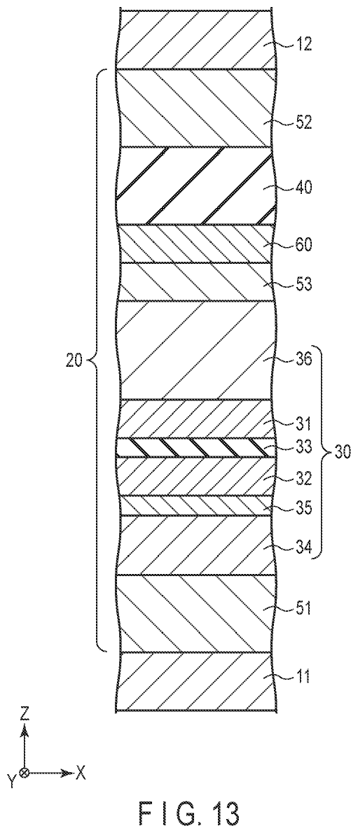

Next, the fifth modified example of this embodiment will be described. FIG. 13 is a cross-sectional view schematically showing a detailed configuration of the memory cells 20 in this modified example.

In this modified example as well, the resistive layer 60 is provided on the upper layer side of the magnetoresistance effect element 30 and on the lower layer side of the wiring line 12, as in the case of the embodiment described above. Further, in this modified example as well, the resistive layer 60 is provided on the lower layer side of the selector 40 as in the case of the fourth modified example described above. Furthermore, in this modified example, the resistive layer 60 is provided on the upper layer side of the middle electrode 53. Moreover, the magnetoresistance effect element 30 is a top-free type magnetoresistance effect element in which the storage layer 31 is located on the upper layer side of the reference layer 32.

In this modified example as well, the resistance of the resistive layer 60 is higher than that of the middle electrode 53, and the resistive layer 60 is provided on the upper layer side of the magnetoresistance effect element 30. Therefore, in this modified example as well, advantageous effects similar to those of the embodiment described above can be obtained.

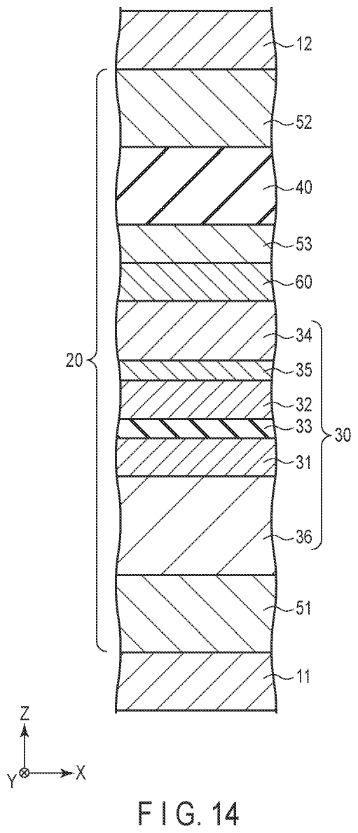

Next, the sixth modified example of this embodiment will be described. FIG. 14 is a cross-sectional view schematically showing a detailed configuration of the memory cells 20 in this modified example.

In this modified example, the resistive layer 60 is provided on the upper layer side of the magnetoresistance effect element 30 and on the lower layer side of the wiring line 12, as in the case of the embodiment described above. Further, in this modified example as well, the resistive layer 60 is provided on the lower layer side of the selector 40 as in the case of the fourth modified example described above. Furthermore, in this modified example, the resistive layer 60 is provided on the lower layer side of the middle electrode 53. Moreover, the magnetoresistance effect element 30 is a bottom-free type magnetoresistance effect element in which the storage layer 31 is located on the lower layer side of the reference layer 32.

In this modified example as well, the resistance of the resistive layer 60 is higher than that of the middle electrode 53, and the resistive layer 60 is provided on the upper layer side of the magnetoresistance effect element 30. Therefore, in this modified example as well, advantageous effects similar to those of the embodiment described above can be obtained.

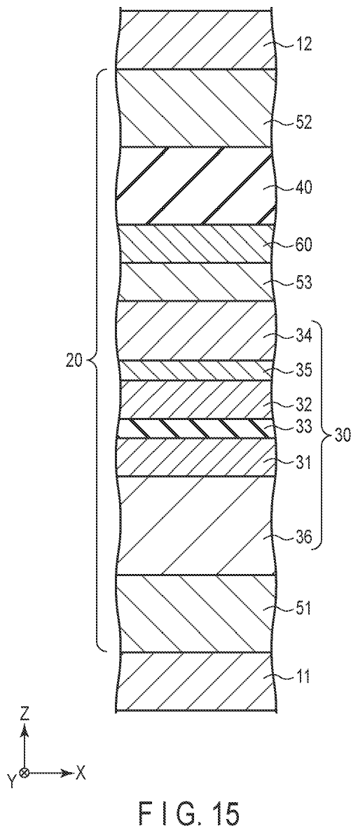

Next, the seventh modified example of this embodiment will be described. FIG. 15 is a cross-sectional view schematically showing a detailed configuration of the memory cells 20 in this modified example.

In this modified example as well, the resistive layer 60 is provided on the upper layer side of the magnetoresistance effect element 30 and on the lower layer side of the wiring line 12 as in the case of the embodiment described above. Further, in this modified example as well, the resistive layer 60 is provided on the lower layer side of the selector 40 as in the case of the fourth modified example described above. Furthermore, in this modified example, the resistive layer 60 is provided on the upper layer side of the middle electrode 53. Moreover, the magnetoresistance effect element 30 is a bottom-free type magnetoresistance effect element in which the storage layer 31 is located on the lower layer side of the reference layer 32.

In this modified example as well, the resistance of the resistive layer 60 is higher than that of the middle electrode 53, and the resistive layer 60 is provided on the upper layer side of the magnetoresistance effect element 30. Therefore, in this modified example as well, advantageous effects similar to those of the embodiment described above can be obtained.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A memory device comprising:
a first wiring line extending along a first direction;
a second wiring line provided on an upper layer side of the first wiring line and extending along a second direction intersecting the first direction; and
a memory cell provided between the first wiring line and the second wiring line, and including a magnetoresistance effect element, a switching element, a middle electrode provided between the magnetoresistance effect element and the switching element, and a resistive layer provided between the magnetoresistance effect element and the second wiring line,
wherein
a resistance of the resistive layer is higher than a resistance of the middle electrode.

2. The memory device of claim 1, wherein
the magnetoresistance effect element is provided on an upper layer side of the switching element.

3. The memory device of claim 1, wherein
the magnetoresistance effect element is provided on a lower layer side of the switching element.

4. The memory device of claim 3, wherein
the resistive layer is provided on an upper layer side of the switching element.

5. The memory device of claim 3, wherein
the resistive layer is provided on a lower layer side of the switching element.

6. The memory device of claim 1, wherein
the resistive layer is formed of a semiconductor material.

7. The memory device of claim 1, wherein
the middle electrode is formed of a material containing titanium (Ti) and nitrogen (N), a material containing tungsten (W) and nitrogen (N), or a material containing tantalum (Ta) and nitrogen (N).

8. The memory device of claim 1, wherein
the magnetoresistance effect element includes:
a first magnetic layer having a variable magnetization direction;
a second magnetic layer having a fixed magnetization direction; and
a nonmagnetic layer provided between the first magnetic layer and the second magnetic layer.

9. The memory device of claim 8, wherein
the magnetoresistance effect element further includes a third magnetic layer,
the second magnetic layer is provided between the nonmagnetic layer and the third magnetic layer, and
the second magnetic layer and the third magnetic layer are antiferromagnetically coupled to each other.

10. The memory device of claim 8, wherein
the magnetoresistance effect element further includes an auxiliary layer that enhances a perpendicular magnetic anisotropy of the first magnetic layer, and
the first magnetic layer is provided between the nonmagnetic layer and the auxiliary layer.

11. The memory device of claim 1, wherein
the switching element is a two-terminal type switching element, and has a characteristic of changing from an off state to an on state when a voltage applied between two terminals thereof is higher than a threshold voltage.
